(19) United States
(12) Patent Application Publication
(10) Pub. No.: US 2025/0259911 A1
(43) Pub. Date: Aug. 14, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chun-Yuan CHEN, Hsinchu (TW); Huan-Chieh SU, Changhua (TW); Chih-Hao WANG, Hsinchu (TW)

(21) Appl. No.: 18/676,598

(22) Filed: May 29, 2024

Related U.S. Application Data
(60) Provisional application No. 63/551,673, filed on Feb. 9, 2024.

(51) Int. Cl. H01L 23/48; H01L 21/768; H01L 29/06; H01L 29/423; H01L 29/66; H01L 29/775

(52) U.S. Cl. CPC H01L 23/481; H01L 21/76852; H01L 21/76898; H10D 30/014; H10D 30/43; H10D 30/6735; H10D 62/121

(57) ABSTRACT

Embodiments of the present disclosure provide semiconductor device structures and methods of forming the same. The structure includes a first conductive feature disposed between two substrate portions, a second conductive feature disposed over the first conductive feature, a third conductive feature disposed over the first conductive feature, and a fourth conductive feature disposed over the first conductive feature. The fourth conductive feature includes a top portion disposed over the second and third conductive features and a bottom portion disposed between the second and third conductive features, and the first, second, third, and fourth conductive features are electrically connected.

### CROSS-REFERENCE TO RELATED APPLICATIONS

This application claims priority to U.S. Provisional Application Ser. No. 63/551,673 filed on Feb. 9, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15 are perspective views of various stages of manufacturing a semiconductor device structure, in accordance with some embodiments.

FIGS. 16A-19A are perspective views of various stages of manufacturing the semiconductor device structure, in accordance with some embodiments.

FIGS. 16B-19B are cross-sectional side views of various stages of manufacturing the semiconductor device structure taken along line A-A of FIG. 16A, in accordance with some embodiments.

FIG. 18B-1 is a cross sectional side view of one of various stages of manufacturing the semiconductor device structure taken along line A-A of FIG. 16A, in accordance with alternative embodiments.

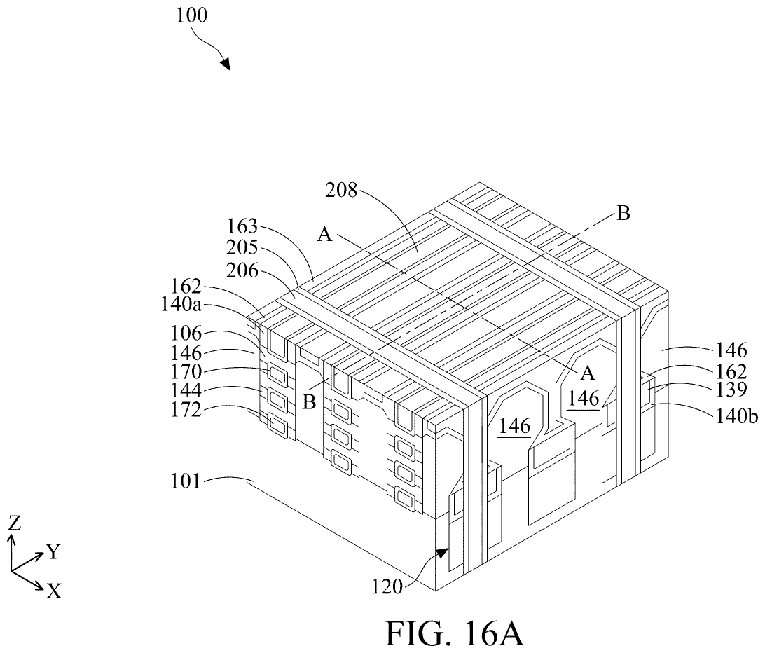

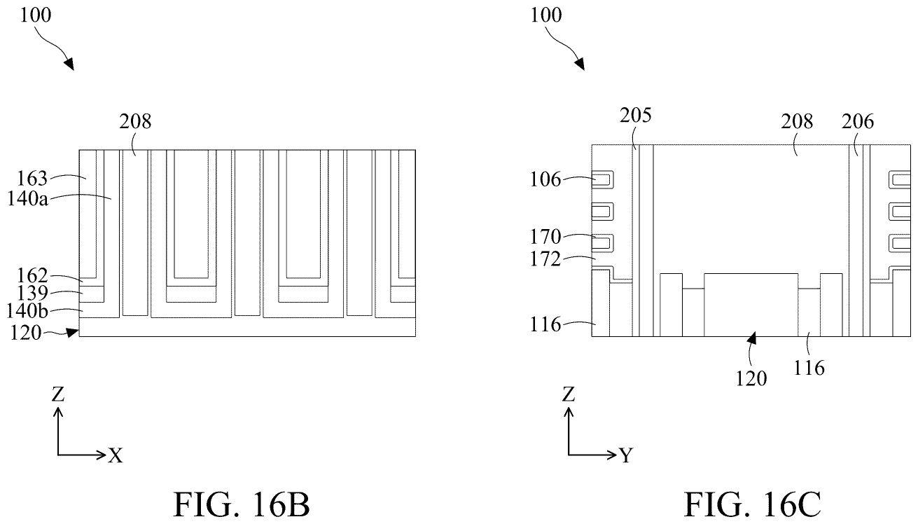

FIGS. 16C-19C are cross-sectional side views of various stages of manufacturing the semiconductor device structure taken along line B-B of FIG. 16A, in accordance with some embodiments.

FIGS. 20A-20D are perspective views of various stages of manufacturing the semiconductor device structure, in accordance with some embodiments.

FIGS. 21A-21B are cross sectional side views of one of various stages of manufacturing the semiconductor device structure taken along lines A-A, B-B of FIG. 16A, respectively, in accordance with some embodiments.

FIGS. 22A and 22B are perspective views of a feed through via (FTV) cell, in accordance with some embodiments.

FIG. 23 is a top view of the semiconductor device structure, in accordance with some embodiments.

FIG. 24 is a perspective view of the semiconductor device structure, in accordance with some embodiments.

FIGS. 25A-25B are cross-sectional side views of one of various stages of manufacturing the semiconductor device structure taken along lines A-A, B-B of FIG. 16A, respectively, in accordance with alternative embodiments.

FIG. 26 is a cross-sectional side view of one of various stages of manufacturing the semiconductor device structure taken along line A-A of FIG. 16A, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

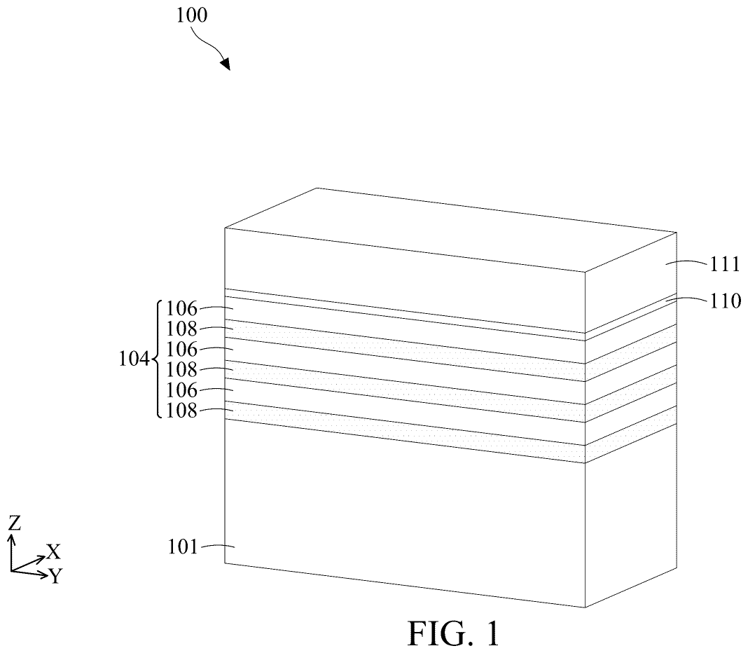

FIGS. 1 to 21B show exemplary processes for manufacturing a semiconductor device structure 100 according to embodiments of the present disclosure. It is understood that additional operations can be provided before, during, and after processes shown by FIGS. 1 to 21B, and some of the operations described below can be replaced or eliminated, for additional embodiments of the method. The order of the operations/processes is not limiting and may be interchangeable.

FIGS. 1 to 15 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

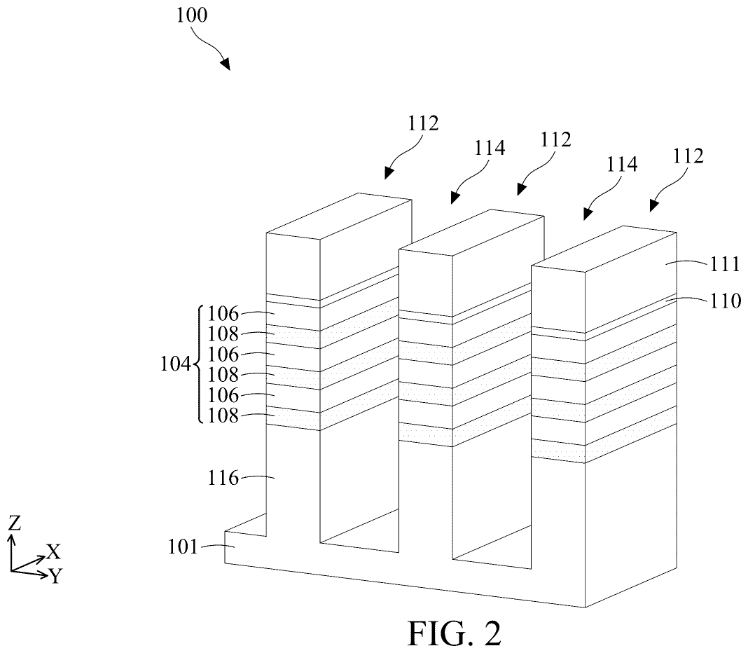

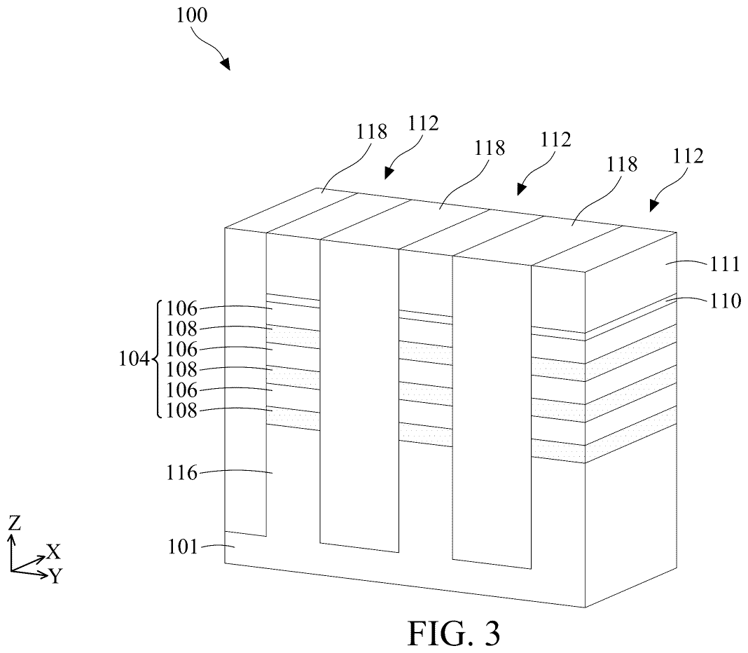

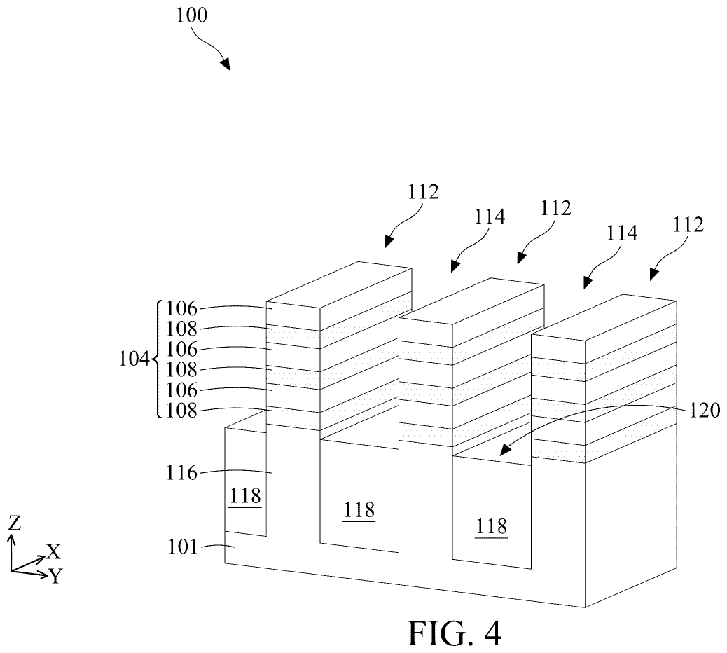

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

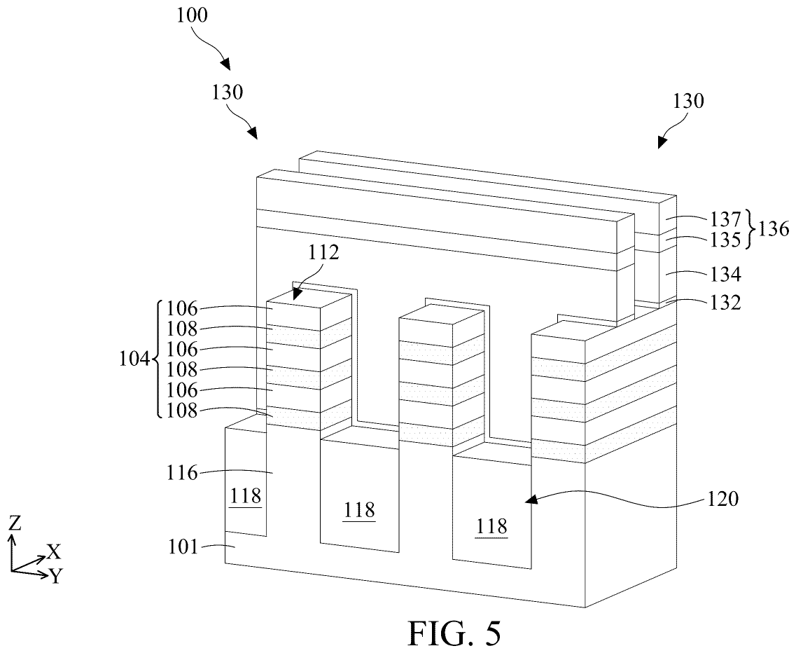

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

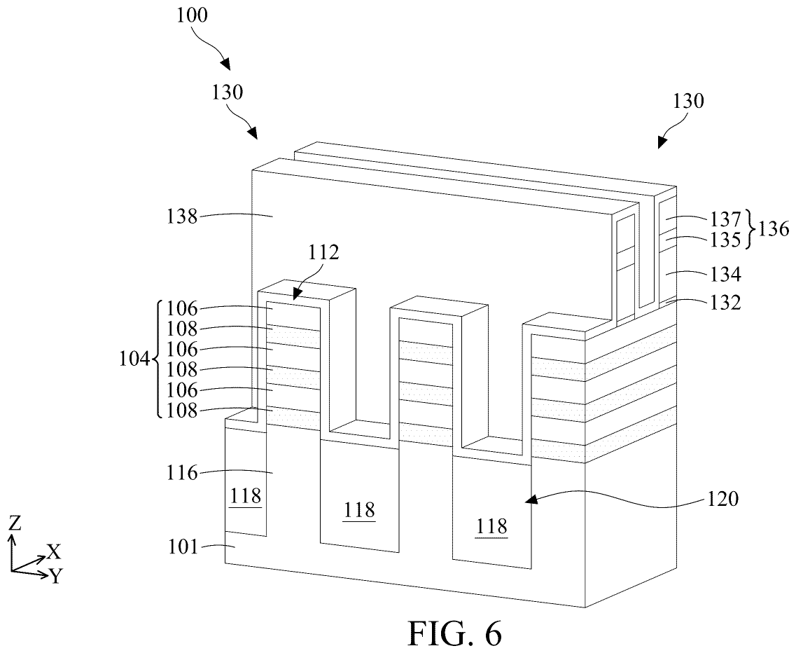

In FIG. 6, a spacer layer 138 is formed to cover the sacrificial gate structures 130, the second portions of the fin structures 112, and the second portions of the isolation regions 120. The spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the spacer layer 138 is formed by a conformal process, such as an atomic layer deposition (ALD) process. In some embodiments, the spacer layer 138 has a thickness ranging from about 2 nm to about 10 nm.

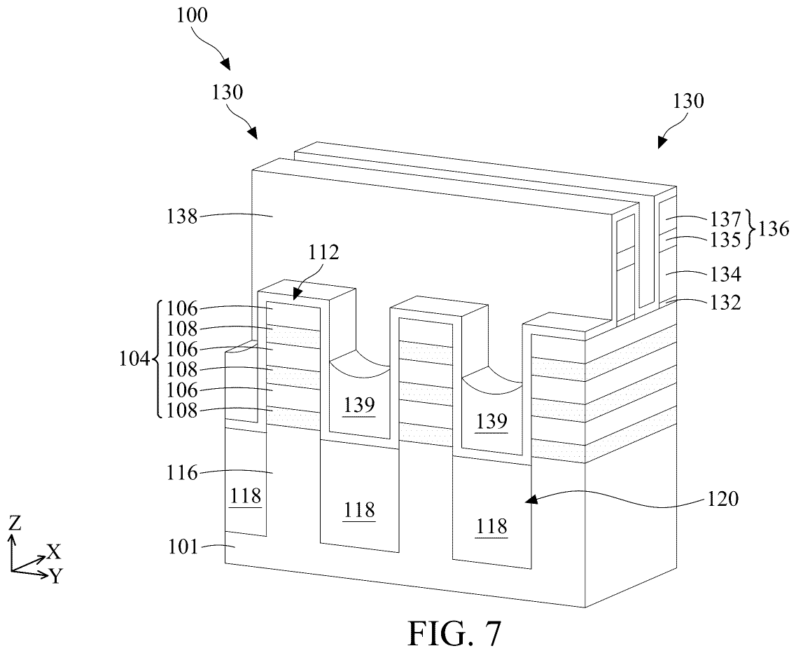

In FIG. 7, a mask 139 is formed between adjacent second portions of the fin structures 112. The mask 139 is formed on the portion of the spacer layer 138 formed on the second portions of the isolation regions 120. The mask 139 may include any suitable material having different etch selectivity compared to the material(s) of the spacer layer 138. In some embodiments, the mask 139 is a bottom anti-reflective coating (BARC) layer. In some embodiments, the mask 139 is a dielectric layer having a different etch selectivity from the spacer layer 138. The mask 139 may be formed by a two-step process. First, a mask layer is formed on the sacrificial gate structures 130 and the second portions of the fin structures 112. The mask layer may include the same material as the mask 139 and may be formed by any suitable process, such as spin coating. Then, an etch back process is performed to remove portions of the mask layer to form the mask 139. As shown in FIG. 7, the mask 139 has a height along the Z direction that is less than a height of the fin structure 112. The mask 139 protects the portions of the spacer layer 138 formed on the second portions of the isolation regions 120 during subsequent processes. In some embodiments, as shown in FIG. 7, the top surface of the mask 139 is located between the top surface and the bottom surface of the second topmost first semiconductor layer 106.

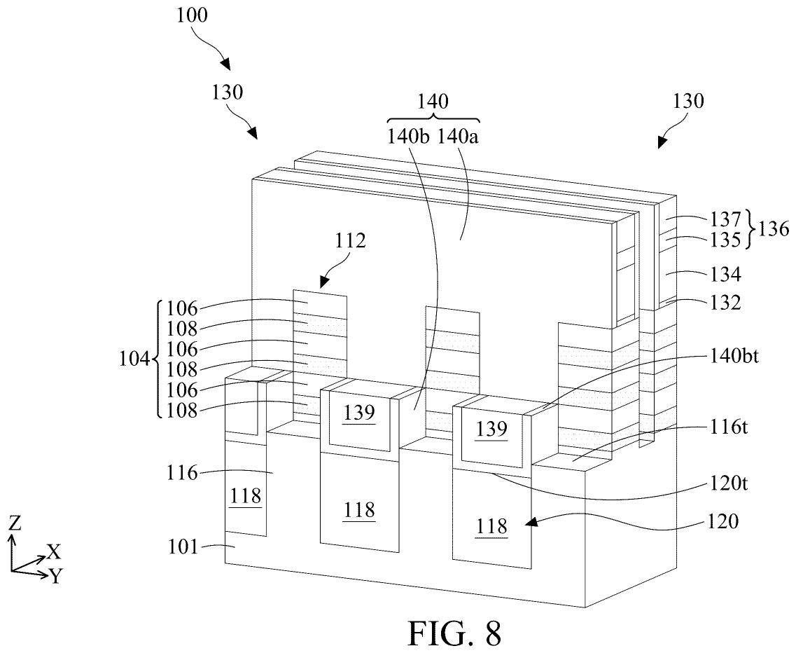

In FIG. 8, one or more etch processes are performed to recess the portions of the fin structures 112 not covered by the sacrificial gate structures 130 (and the portions of the spacer layer 138 formed on sidewalls of the sacrificial gate structures 130) and to remove portions of the spacer layer 138. In some embodiments, the portions of the spacer layer 138 formed on tops of the portions of the fin structures 112 not covered by the sacrificial gate structures 130 are removed to expose the portions of the fin structures 112 not covered by the sacrificial gate structures 130. Then, the exposed portions of the fin structures 112 not covered by the sacrificial gate structures 130 are recessed to expose the substrate portions 116, as shown in FIG. 8. The portions of the spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form spacers 140 including a first portion 140a formed on sidewalls of the sacrificial gate electrode layer 134 and second portions 140b formed on the second portions of the isolation regions 120 not covered by the sacrificial gate structures 130. The mask 139 protects the second portions 140b of the spacers 140 during the one or more etch processes. In some embodiments, the second portion 140b of each spacer 140 has a “U” shape, as shown in FIG. 8. In some embodiments, after the one or more etch processes, the height of the mask 139 is substantially less than a height of the vertical portions of the second portion 140b of the spacer 140.

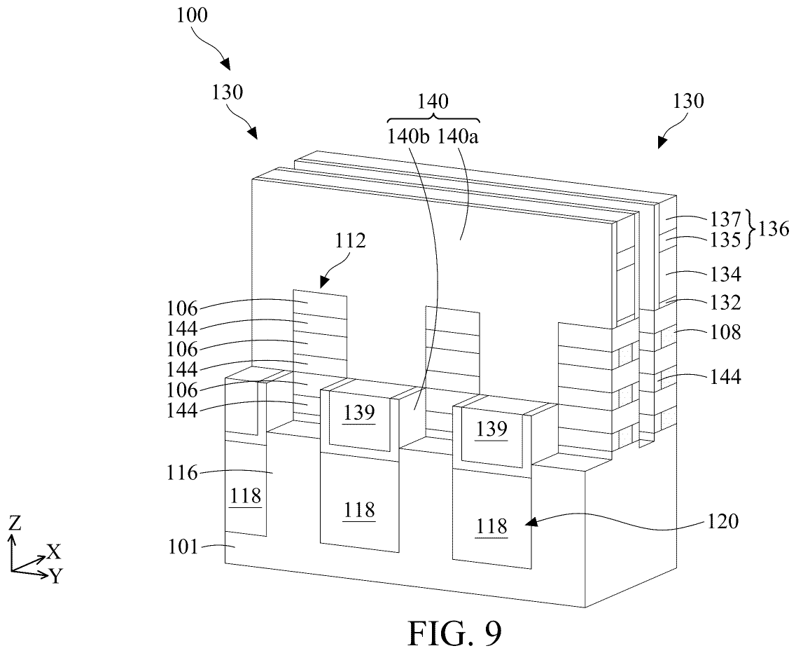

In FIG. 9, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. In one embodiment, the dielectric spacer 144 includes SiONC. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

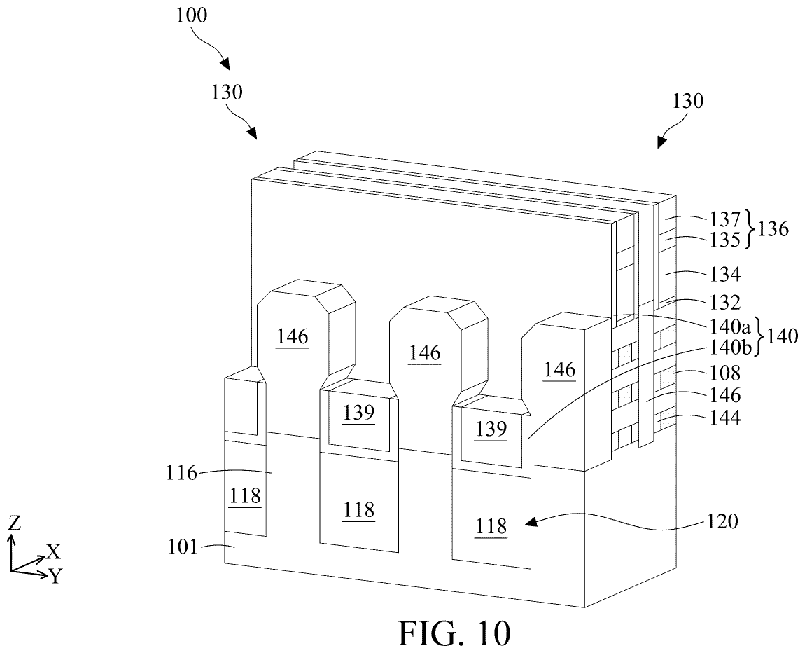

In FIG. 10, source/drain (S/D) regions 146 are formed from the substrate portion 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. The S/D region 146 may include doped and undoped epitaxial materials.

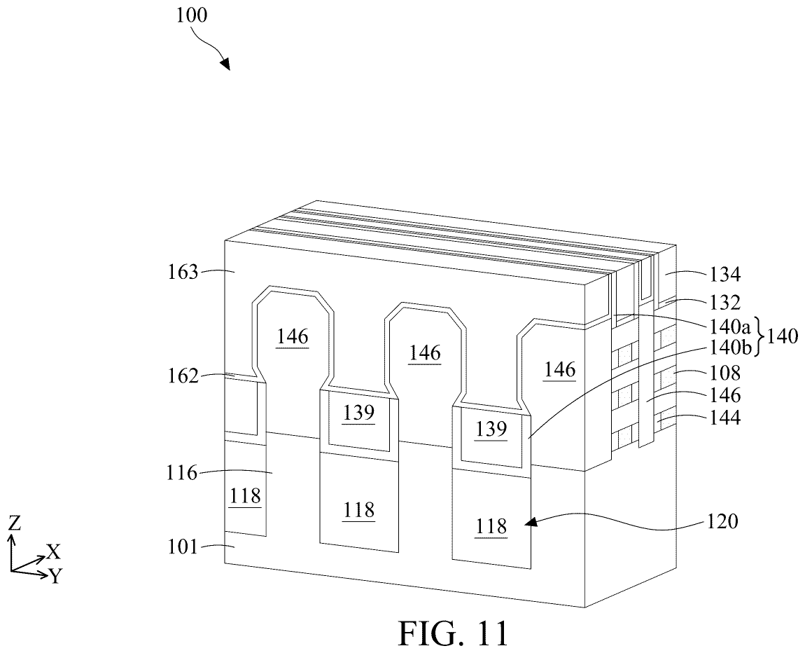

In FIG. 11, a contact etch stop layer (CESL) 162 is conformally formed on the exposed surfaces of the semiconductor device structure 100. The CESL 162 covers the sidewalls of the first portion 140a of the spacers 140 and is disposed on the mask 139 and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 11. The planarization process may be any suitable process, such as a CMP process. The planarization process removes portions of the ILD layer 163 and the CESL 162 disposed on the sacrificial gate structures 130. The planarization process may also remove the mask layer 136.

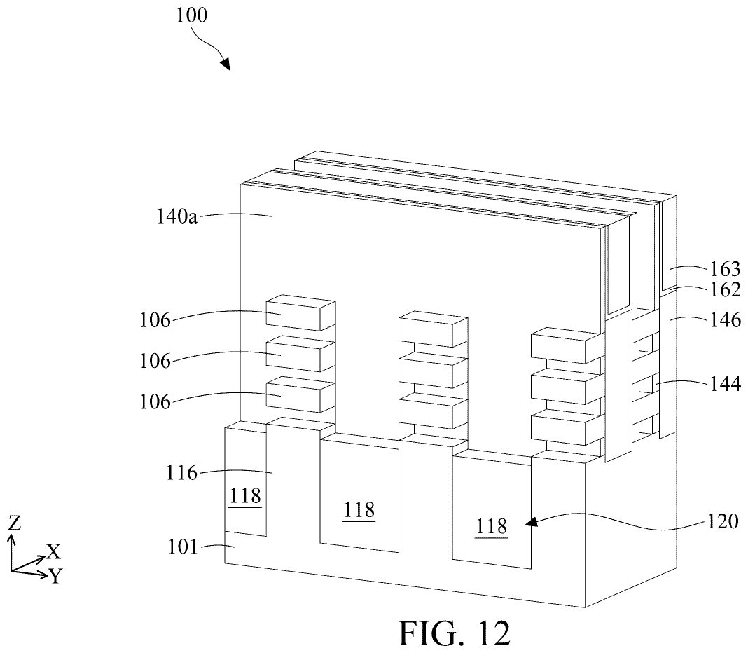

In FIG. 12, the sacrificial gate structures 130 and the second semiconductor layers 108 are removed. The ILD layer 163 protects the S/D regions 146 during the removal processes. The sacrificial gate structure 130 and the second semiconductor layers 108 can be removed using plasma dry etching and/or wet etching. In some embodiments, a wet etchant such as a tetramethylammonium hydroxide (TMAH) solution can be used to selectively remove the sacrificial gate structures 130 and the second semiconductor layers 108 but not the spacers 140, the isolation regions 120, the ILD layer 163, and the CESL 162.

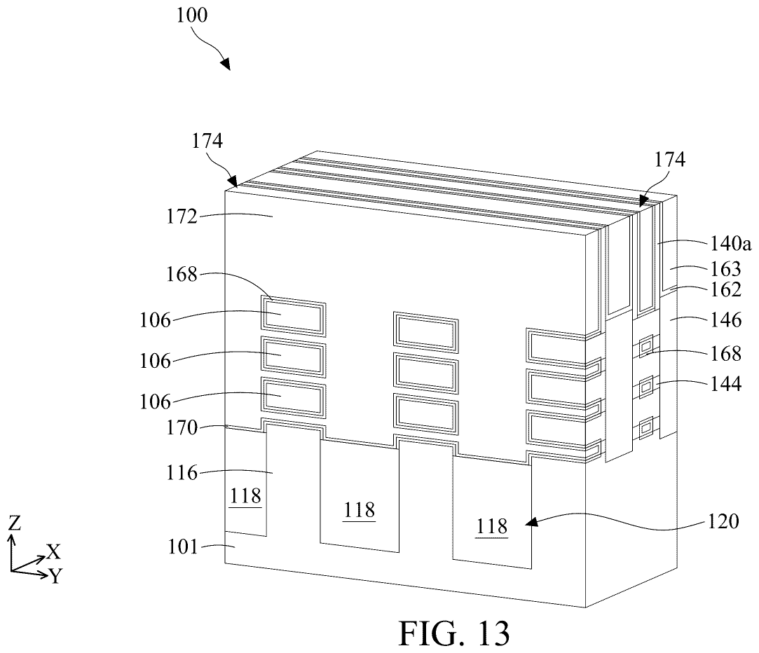

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170, as shown in FIG. 13. The gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

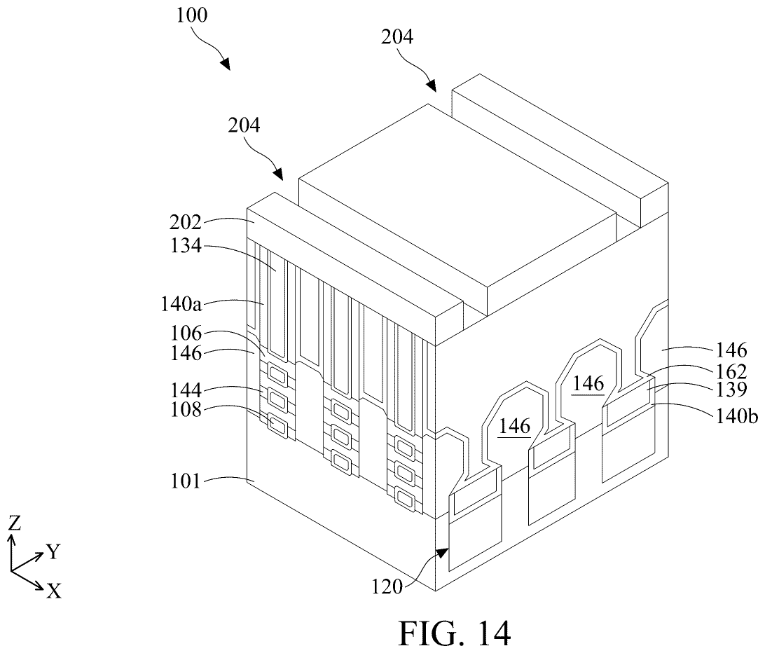

In FIG. 14, a hard mask 202 is formed on the ILD layer 163. The hard mask 202 may include a dielectric material, such as SiN, SiCN, SiOCN, SiOC, or other suitable dielectric material. The hard mask 202 may be used to form one or more openings 204 in the gate structures 174, the ILD layer 163, the CESL 162, and the isolation regions 120. The openings 204 may be formed between adjacent S/D regions 146. In the channel regions, the openings 204 are formed in the gate electrode layer 172, the gate dielectric layer 170, and the isolation regions 120. The openings 204 may be formed to separate the gate structure 174 into multiple portions (or to separate the gate electrode layer 172 into multiple gate electrode layers 172). The openings 204 may be formed by one or more etch processes. In some embodiments, portions of the substrate 101 are exposed in the openings 204.

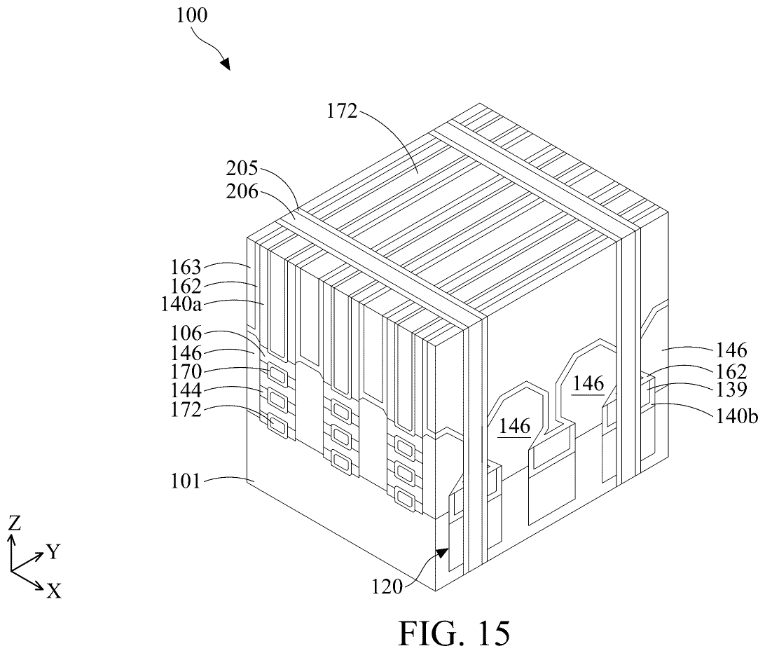

In FIGS. 15, a liner 205 and a dielectric material 206 are formed in each opening 204. The liner 205 and the dielectric material 206 may include any suitable dielectric materials. In some embodiments, the liner 205 includes the same material as the CESL 162, and the dielectric material 206 includes the same material as the ILD layer 163. After filling the openings 204 with the liner 205 and the dielectric material 206, a planarization process, such as a CMP process, may be performed to expose the gate electrode layers 172, as shown in FIG. 15. The processes performed in FIGS. 14 and 15 may be referred to as a cut metal gate (CMG) process.

FIGS. 16A-19A are perspective views of various stages of manufacturing the semiconductor device structure 100, in accordance with some embodiments. FIGS. 16B-19B are cross-sectional side views of various stages of manufacturing the semiconductor device structure 100 taken along line A-A of FIG. 16A, in accordance with some embodiments. FIGS. 16C-19C are cross-sectional side views of various stages of manufacturing the semiconductor device structure 100 taken along line B-B of FIG. 16A, in accordance with some embodiments. As shown in FIGS. 16A-16C, in some embodiments, portions of the gate structures 174 located between two dielectric materials 206 are removed and replaced with dielectric materials 208. In some embodiments, portions of three or more gate structures 174 are replaced with the dielectric materials 208. In some embodiments, a mask (not shown) is formed to expose portions of the gate structures 174 to be removed. Next, one or more processes are performed to remove the exposed portions of the gate structures 174. In some embodiments, both the gate dielectric layers 170 and the gate electrode layers 172 are removed by the one or more processes. In some embodiments, the gate dielectric layers 170 are not removed and remain in the semiconductor device structure 100. The removal of the gate structures 174 form openings in the semiconductor device structure 100, and the openings may extend into or through the isolation regions 120. In some embodiments, as shown in FIG. 16C, portions of the substrate portion 116 may also be removed.

Next, the dielectric material 208 is deposited in each opening. The dielectric material 208 may include any suitable dielectric material, such as a compound of Si, O, C, and N, or other high-k materials. In some embodiments, the dielectric material 208 includes SiN. In some embodiments, a liner (not shown) may be first deposited into the openings, and the dielectric material 208 is deposited on the liner in the openings. In some embodiments, the liner may include the same material as the liner 205, and the dielectric material 208 may include the same material as the dielectric material 206. After depositing the dielectric material 208, a planarization process, such as a CMP process, is performed to expose the dielectric material 206 and the gate structures 174. The processes of replacing portions of the gate structures 174 with the dielectric materials 208 may be referred to as a continuous polysilicon on diffusion (CPODE) process, which is to form an isolation region that divide active region into multiple segments. In some embodiments, the isolation region may be used to form a feed through via (FTV) cell that electrically connects the front side of the substrate 101 and the back side of the substrate 101. The FTV cell is described in detail below. In some embodiments, the isolation region is defined by three dielectric materials 208, as shown in FIG. 16A, and the FTV cell has a dimension in the X direction of two times the contact poly pitch (CPP), which defines a minimum center-to-center space between gate electrode layers of adjacent transistors. In some embodiments, the isolation region is defined by a plurality of dielectric materials 208, and the FTV cell has a dimension in the X direction of six times the CPP or more. The dimension of the FTV cell in the Y direction may be defined by the adjacent dielectric materials 206, as shown in FIG. 16A. In some embodiments, the distance between the center points of adjacent dielectric materials 206 may be referred to as the cell height.

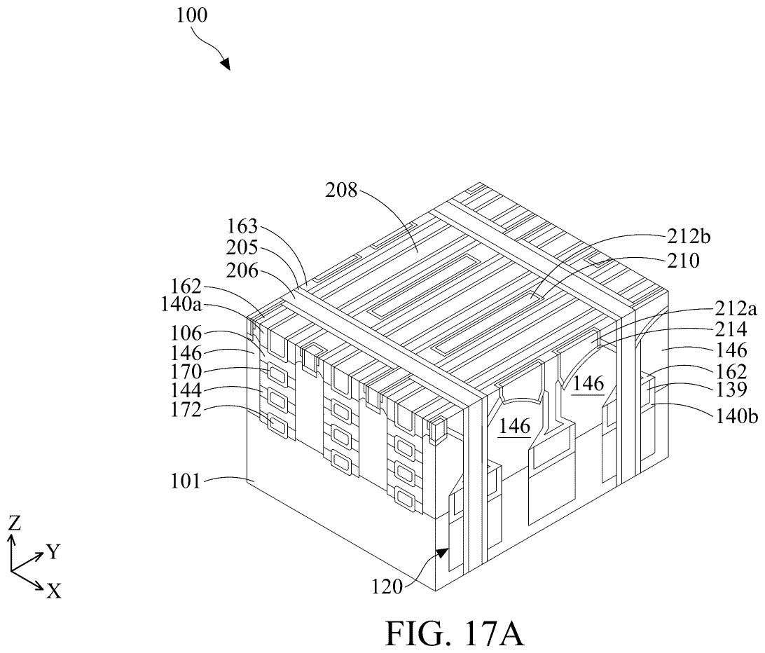

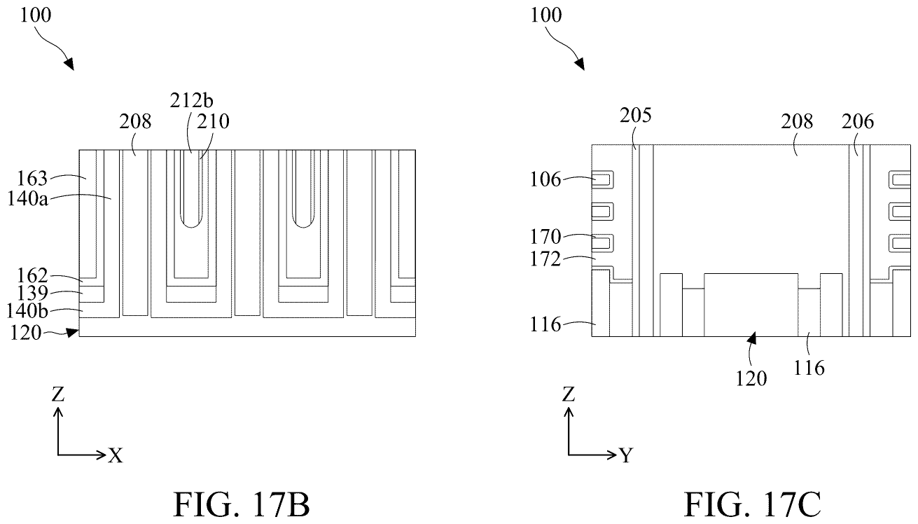

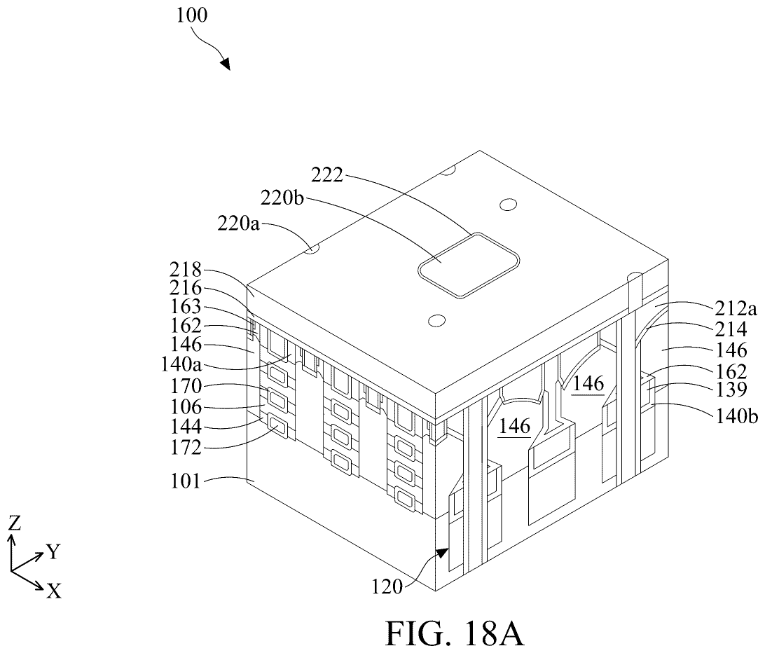

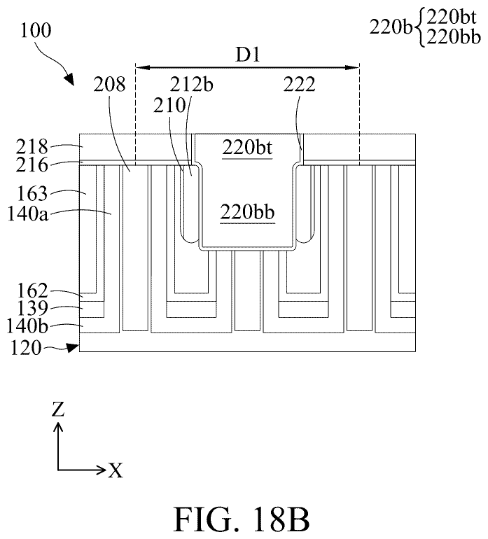

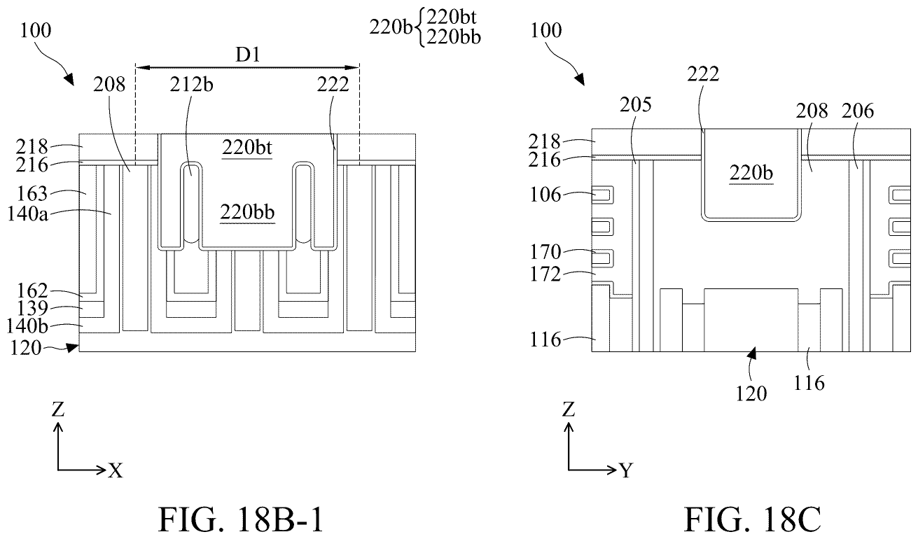

In FIGS. 17A-17C, conductive features 212a, 212b are formed in the ILD layer 163. The conductive features 212a are formed to provide electrical paths to the S/D regions 146. The conductive features 212b are formed to prevent CMP dishing and/or to help with lithography loading effects. Furthermore, the conductive features 212b are formed to reduce electrical resistance in the FTV cell. In some embodiments, the conductive features 212b may be slot conductive contacts. For example, the conductive features 212b may extend over two S/D regions 146, as shown in FIG. 17A. In some embodiments, two conductive features 212b are formed in the ILD layer 163, and the dielectric material 208 is disposed between the two conductive features 212b, as shown in FIG. 17A. In some embodiments, more than two conductive features 212b are formed, such as three or more conductive features 212b disposed spaced apart along the X direction, and the dielectric material 208 is located between adjacent conductive features 212b. In some embodiments, the conductive features 212b are located inside of the dielectric materials 208 along the X direction, and the outmost dielectric materials 208 along the X direction separate the conductive features 212b and the subsequently formed conductive feature 220b (FIG. 18A-18C) from active devices adjacent the isolation region. In other words, the dielectric materials 208 are located at the opposite ends of the FTV cell along the X direction.

The conductive features 212a, 212b may include an electrically conductive material, such as a metal. In some embodiments, the conductive features 212a, 212b includes a material having one or more of Ru, Mo, Co, Ni. W, Ti, Ta, Cu, Al, TiN or TaN, and the conductive features 212a, 212b may be formed by any suitable method, such as electro-chemical plating (ECP), or PVD. In some embodiments, the conductive features 212a, 212b include W or Co. A silicide layer 214 may be formed between each conductive feature 212a, 212b and the corresponding S/D region 146, as shown in FIG. 17A. The silicide layer 214 may include a material having one or more of WSi, CoSi, NiSi, TiSi, MoSi and TaSi.

In some embodiments, a liner 210 is formed in the openings prior to forming the conductive features 212a, 212b. The liner 210 may include any suitable material. In some embodiments, the liner 210 is a metal nitride and is a result of the process for forming the silicide layers 214. A mask (not shown) may be used to form the conductive features 212a, 212b, and the mask may be removed after the formation of the conductive features 212a, 212b. A planarization process may be performed after the formation of the conductive features 212a, 212b, and the resulting semiconductor device structure 100 is shown in FIG. 17A.

In FIGS. 18A-18C, an etch stop layer 216 is deposited on the top surface of the semiconductor device structure 100, a dielectric material 218 is deposited on the etch stop layer 216, and conductive features 220a, 220b are formed in the dielectric material 218. The etch stop layer 216 may include the same material as the CESL 162, and the dielectric material 218 may include the same material as the ILD layer 163. The conductive features 220a are formed to provide electrical paths to the S/D regions 146 and the gate electrode layers 172. In some embodiments, the conductive features 220a are electrically connected to the conductive features 212a. The conductive feature 220b is formed in the FTV cell to electrically connect the front side of the substrate 101 and the back side of the substrate 101. The conductive features 220a, 220b include an electrically conductive material, such as W, Ru, Mo, Cu, Ir, Al, or other suitable material. In some embodiments, the conductive features 220a, 220b may include the same material as the conductive features 212a, 212b. In some embodiments, the conductive features 220a, 220b include a material different from the conductive features 212a, 212b. For example, the conductive features 220a, 220b include Cu, while the conductive features 212a, 212b include W, or Co. In some embodiments, an optional barrier layer 222 is formed to separate the conductive features 220a, 220b from the dielectric material 218 and the dielectric material 208. The optional barrier layer 222 may include Ti, Ta, TiN, or TaN. The optional barrier layer 222 may prevent the diffusion of the material from the conductive features 220a, 220b into the dielectric materials 208, 218.

In some embodiments, the conductive features 220a and the conductive features 220b are formed at different times. For example, a first mask (not shown) may be formed on the dielectric material 218, and the first mask is patterned to form first openings for the conductive features 220a. In some embodiments, the depth of the first openings is equal to the total thickness of the etch stop layer 216 and the dielectric material 218. After forming the conductive features 220a in the first openings, a second mask (not shown) is formed on the semiconductor device structure 100, and the second mask is patterned to form a second opening for the conductive feature 220b. The depth of the second opening is substantially greater than the depth of the first openings. In some embodiments, the depth of the second opening is equal to the thicknesses of the dielectric material 218 and the etch stop layer 216, plus a thickness of a portion of the dielectric material 208. Because of the difference between the first and second depths, separate processes using two masks are performed to form the conductive features 220a, 220b. In some embodiments, the height of the conductive feature 220b along the Z direction is substantially greater than the height of the conductive feature 220a.

In some embodiments, the second opening exposes a portion of each of the two conductive features 212b and the dielectric materials located between the two conductive features 212b, such as the liner 210, the CESL 162, the first portion 140a of the spacer 140, and the dielectric material 208. Next, a selective etch process is performed to recess the dielectric materials, while the conductive features 212b are not substantially affected. The conductive feature 220a is then deposited on the exposed portions of the conductive features 212b and in the second opening.

In some embodiments, the conductive feature 220b includes a top portion 220bt and a bottom portion 220bb, as shown in FIG. 18B. The bottom portion 220bb may be disposed between adjacent conductive features 212b, and the top portion 220bt may be disposed over the adjacent conductive features 212b. The top portion 220bt may have a thickness along the Z direction ranging from about 10 nm to about 30 nm. In some embodiments, the top portion 220bt has a first width along the X direction, the bottom portion 220bb has a second width along the X direction, and the first width is substantially greater than the second width. For example, the first width may be about 20 nm greater than the second width. In some embodiments, the top portion 220bt and the bottom portion 220bb have the same width. In some embodiments, the first width is less than the second width. In some embodiments, the first width is less than a distance D1 defined by the distance between the center lines of the adjacent dielectric materials 208, as shown in FIG. 18B. If the first width is greater than the distance D1, the conductive feature 220b may be too close to the active devices adjacent the FTV cell, which may result in electrical short between the conductive feature 220b and the adjacent active devices. In some embodiments, the distance D1 is equal to two times the CPP.

In some embodiments, the conductive feature 220b is disposed adjacent of opposite side surfaces of each conductive feature 212b, as shown in FIG. 18B-1. In such embodiment, the second opening exposes the two conductive features 212b and the dielectric materials located around the two conductive features 212b, such as the liner 210, the CESL 162, the first portion 140a of the spacer 140, and the dielectric material 208. Next, a selective etch process is performed to recess the dielectric materials, while the conductive features 212b are not substantially affected. The second opening is formed between the conductive features 212b, and the inner surfaces (side surfaces of the conductive features 212b that are facing each other) are exposed in the second opening. Furthermore, the second opening is also formed outside of the conductive features 212b, and the outer surfaces (side surfaces of the conductive features opposite the inner surfaces) of the conductive features 212b are also exposed in the second opening. The conductive feature 220a is then deposited on the conductive features 212b and in the second opening, as shown in FIG. 18B-1. As shown in FIG. 18B-1, in some embodiments, the top portion 220bt of the conductive feature 220b may be a continuous material having a constant width, while the bottom portion 220bb includes multiple discrete segments having different widths. As described above, the width of the conductive feature 220b (e.g., the width of the top portion 220bt) may be less than the distance D1 to avoid electrical short between the conductive feature 220b and the adjacent active devices.

In some embodiments, the conductive feature 220 has a first length along the Y direction, and the first length of the conductive feature 220 may be substantially constant, as shown in FIG. 18C. The dielectric material 208 has a second length along the Y direction. In some embodiments, the first length is substantially less than the second length. Similar to the first width of the conductive feature 220b, if the first length of the conductive feature 220b is greater than the second length, the conductive feature 220b is too close to the active devices adjacent the FTV cell. In other words, the conductive feature 220b would be too close to the active gate electrode layers 172, if the first length is greater than the second length. As described above, the distance between the center points of adjacent dielectric materials 206 is the cell height, and the first length of the conductive feature 220 is substantially smaller than the cell height. A planarization process may be performed after the formation of the conductive features 220a, 220b, and the resulting semiconductor device structure 100 is shown in FIG. 18A.

As shown in FIG. 18B, in some embodiments, a bottom of the conductive feature 220b may be located at about the same level as bottoms of the conductive features 212b. In some embodiments, the bottom of the conductive feature 220b is located at a different level than the bottoms of the conductive features 212b.

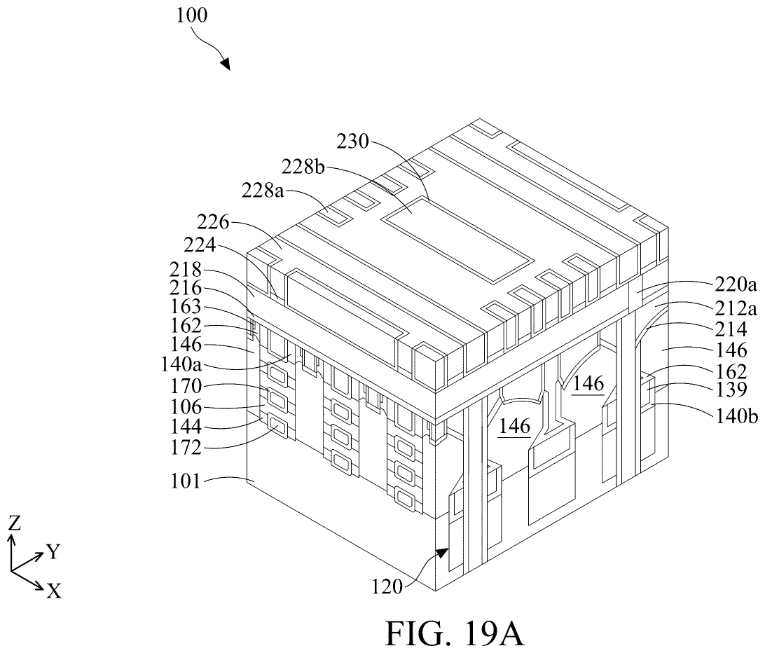

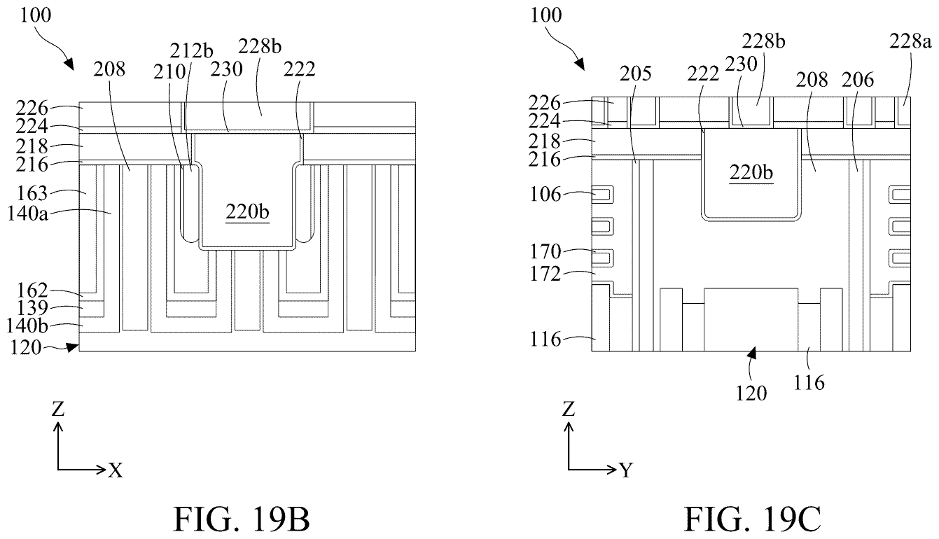

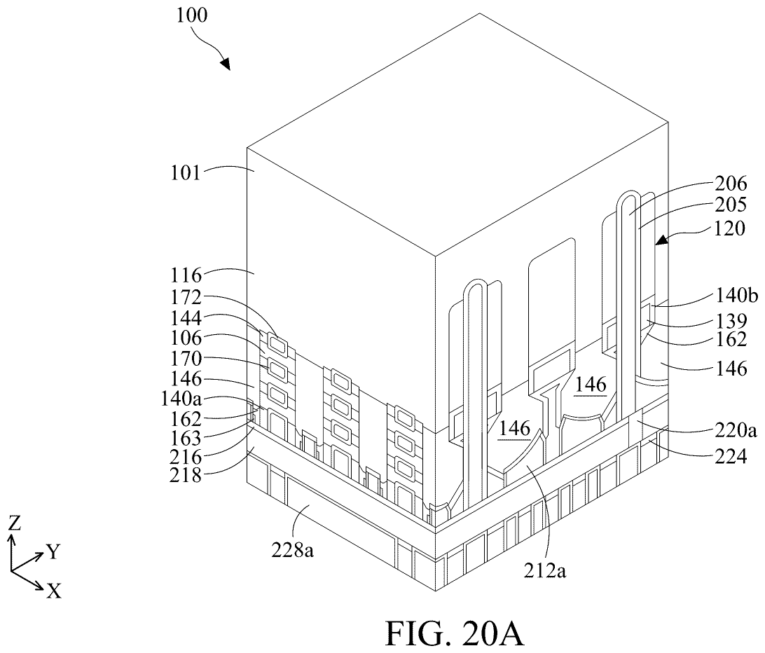

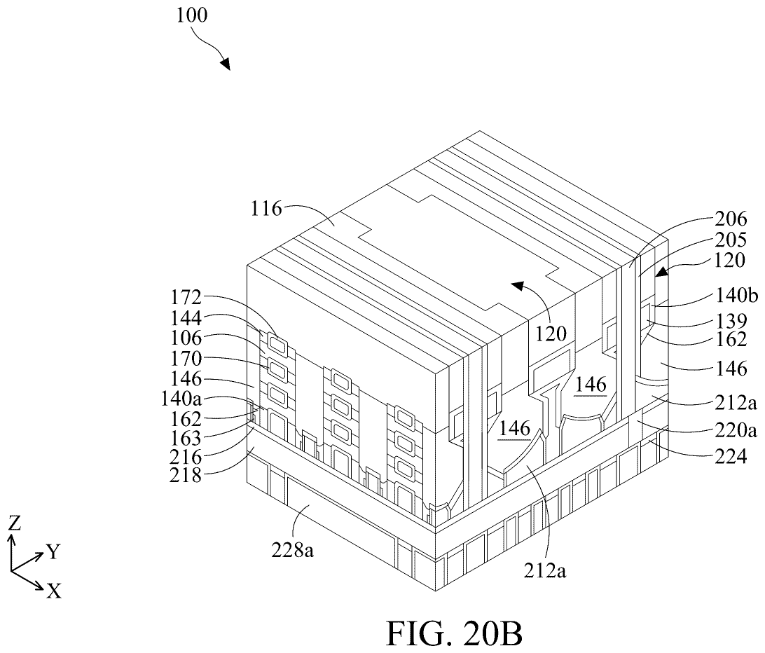

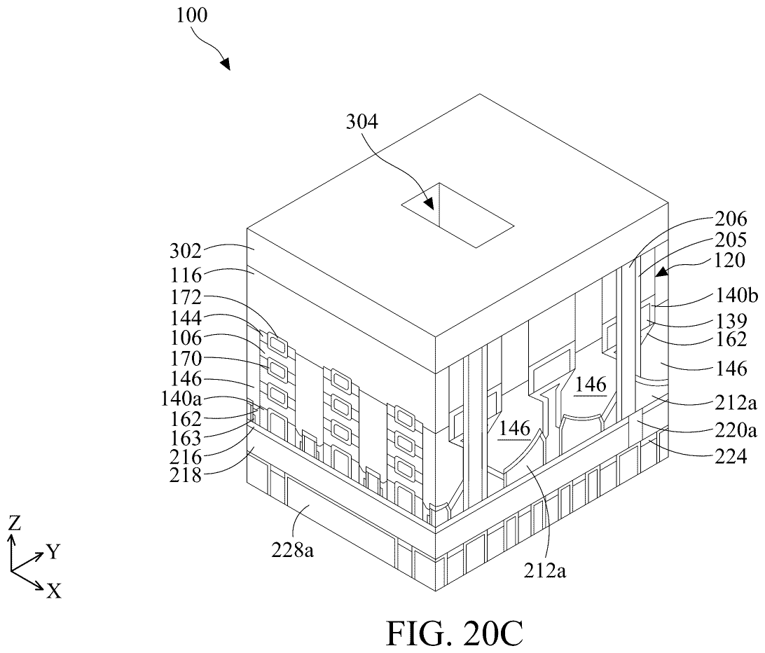

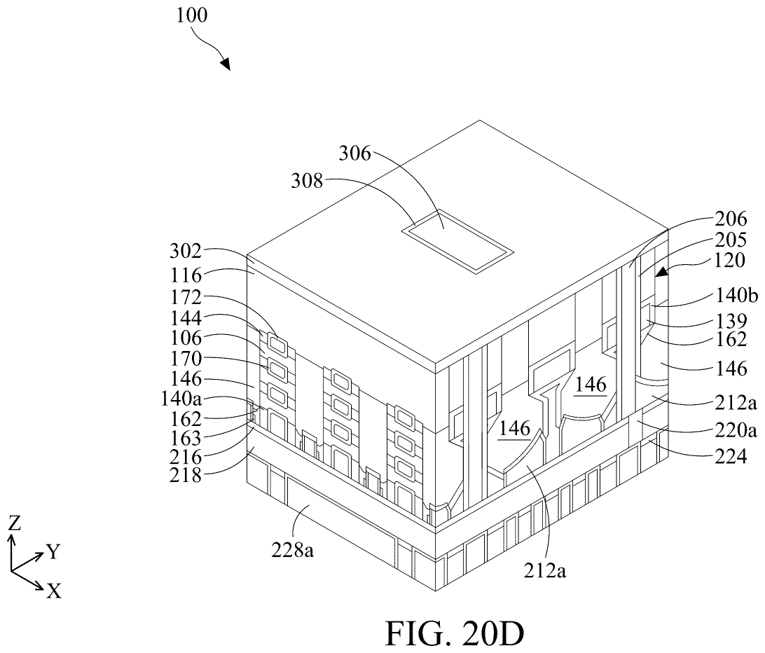

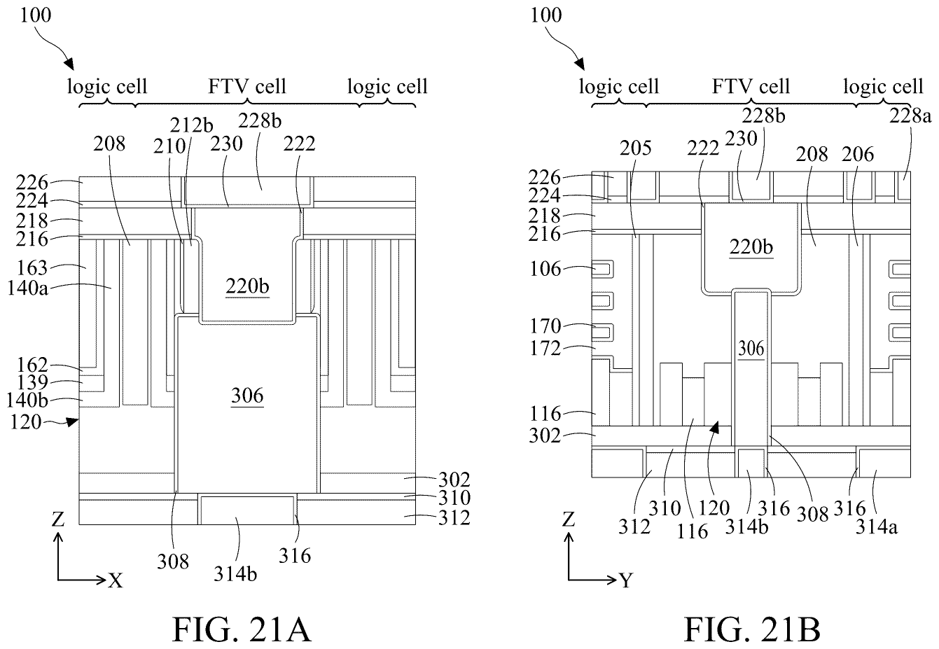

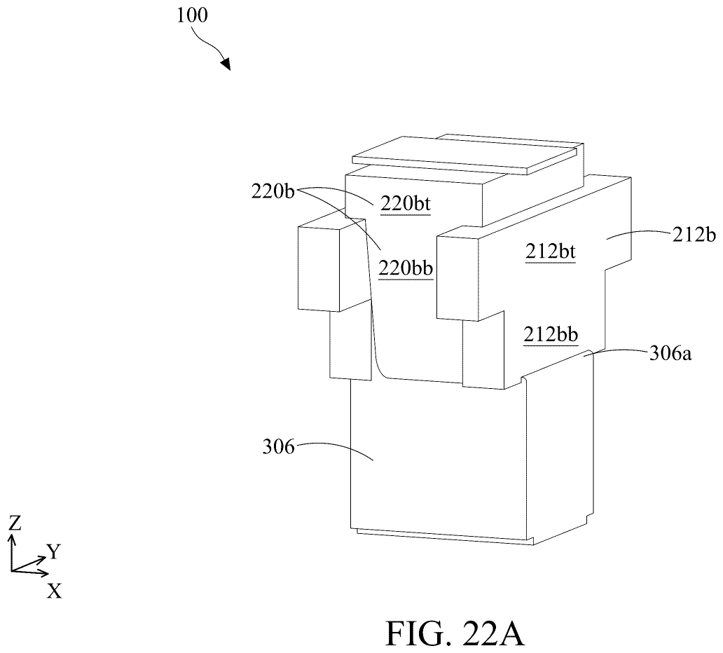

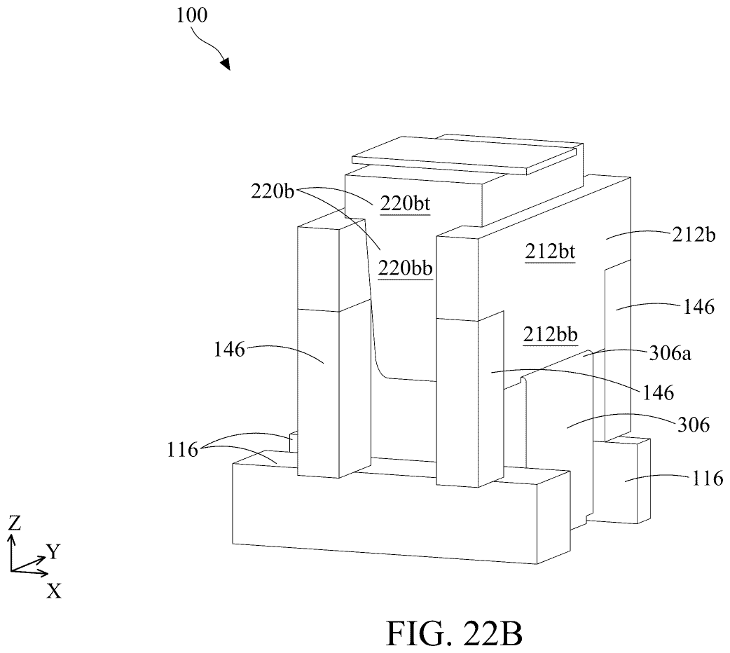

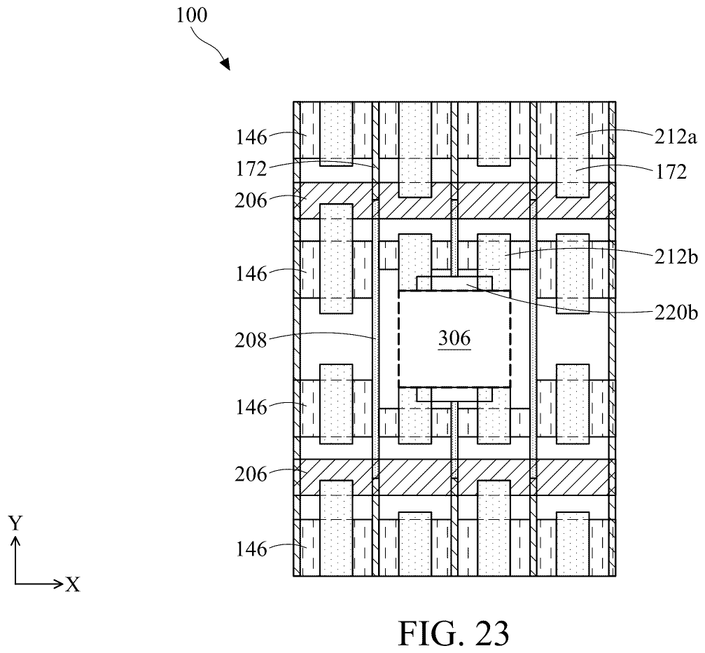

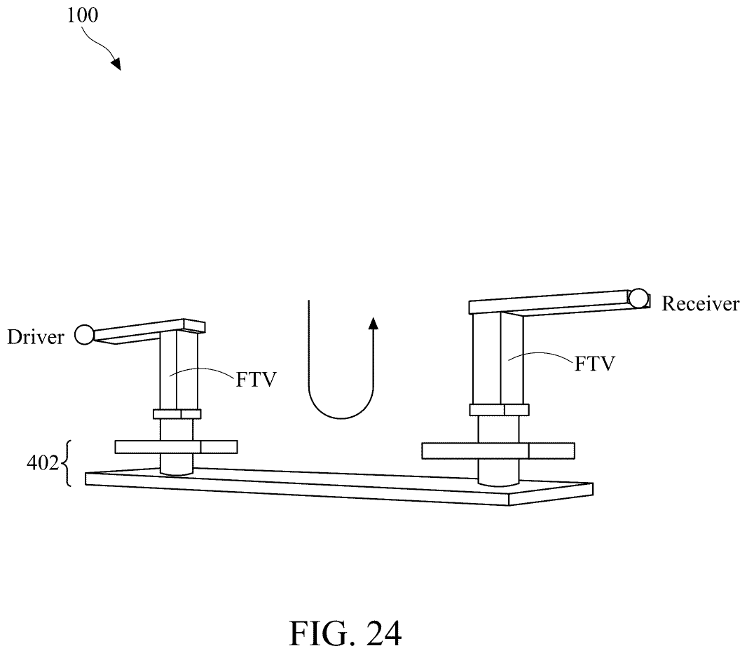

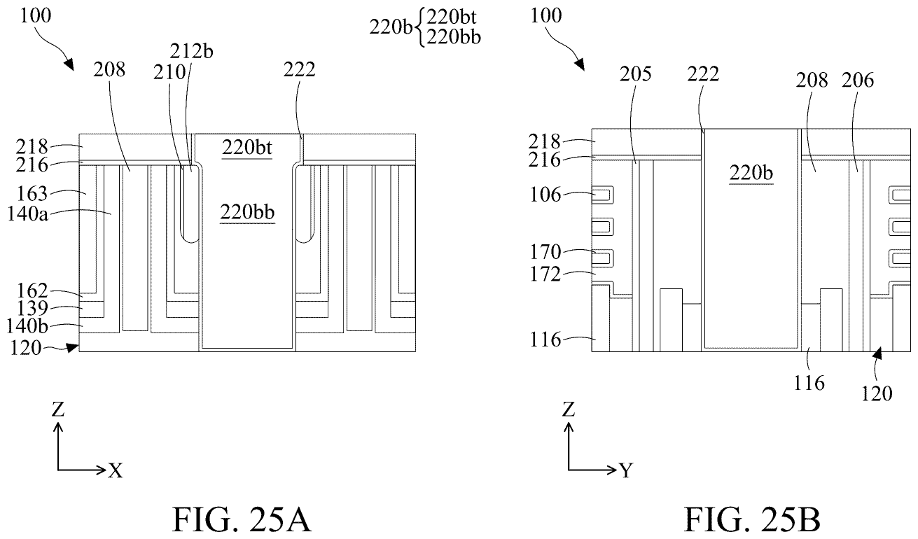

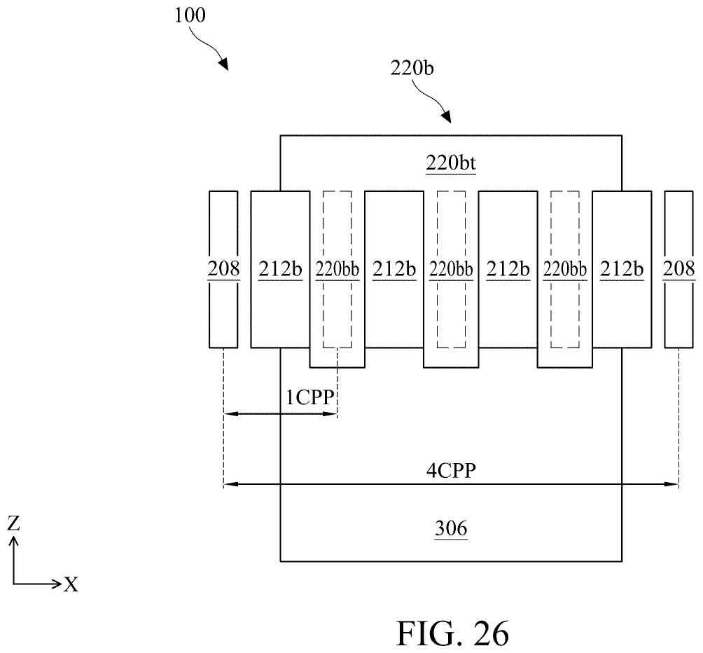

In FIGS. 19A-19C, an etch stop layer 224 is deposited on the top surface of the semiconductor device structure 100, a dielectric material 226 is deposited on the etch stop layer 224, and conductive features 228a, 228b are formed in the dielectric material 226. The etch stop layer 224 may include the same material as the CESL 162. The dielectric material 226 may be an intermetal dielectric (IMD) layer. The dielectric material 226 may be any suitable dielectric material, such as SiOₓ, SiOₓC_{y}H_{z}, or SiOₓC_{y}, where x, y and z are integers or non-integers. The conductive features 228a are formed to provide electrical paths to the S/D regions 146 and the gate electrode layers 172. In some embodiments, the conductive features 228a are electrically connected to the conductive features 220a. The conductive feature 228b are formed to be electrically connected to the conductive feature 220b. The conductive features 228a, 228b may include the same material as the conductive features 220a, 220b. In some embodiments, an optional barrier layer 230 is formed to separate the conductive features 228a, 228b from the dielectric material 226. The optional barrier layer 230 may include the same material as the optional barrier layer 222. In some embodiments, the dielectric material 226 including the conductive features 228a, 228b disposed therein may be the bottommost layer of an interconnect structure formed over a front side of the substrate 101. Subsequent processes may include forming multiple layers of dielectric material with conductive features formed therein.

FIGS. 20A-20D are perspective views of various stages of manufacturing the semiconductor device structure 100, in accordance with some embodiments. Particularly, the processes described in FIGS. 20A-20D are back side processes. After the formation of the interconnect structure (only the bottom most layer of the interconnect structure is shown for clarity), the semiconductor device structure 100 is flipped over, so the substrate 101 is disposed on top. A carrier substrate (not shown) may be first bonded to the interconnect structure prior to the flipping over of the semiconductor device structure 100.

In FIG. 20B, a portion or all of the substrate 101 is removed. The substrate 101 may be removed or thinned down by any suitable process. As shown in FIG. 20B, in some embodiments, the conductive feature 220b (FIG. 19B) is formed between two substrate portions 116. In order to maximize the space for the conductive feature 220b and the subsequently formed conductive feature 306 (FIG. 20D), each of the two substrate portions 116 may have a smaller width along the Y direction in the area where the conductive features 220b, 306 are formed. The removal or thinning down of the substrate 101 exposes the substrate portions 116, the isolation region 120, the liner 205, and the dielectric material 206. The exposed surfaces of the materials may be substantially coplanar, as shown in FIG. 20B.

In FIG. 20C, a mask 302 is formed on the exposed surfaces, and an opening 304 is formed in the mask 302. The mask 302 may include any suitable material. In some embodiments, the mask 302 includes SiN. The opening 304 may be also formed in the isolation region 120, the dielectric material 208, the spacer 140, the mask 139, the CESL 162, and the ILD layer 163. In some embodiments, the conductive feature 220b and the conductive features 212b are exposed in the opening 304.

In FIG. 20D, a conductive feature 306 is formed in the opening 304, and the conductive feature 306 is electrically connected to the conductive feature 220b and the conductive features 212b. The conductive feature 306 includes an electrically conductive material, such as W, Ru, Mo, Cu, Ir, Al, or other suitable material. In some embodiments, the conductive feature 306 may include the same material as the conductive feature 220b. In some embodiments, an optional barrier layer 308 may be formed in the opening 304, and the conductive feature 306 is deposited on the barrier layer 308. The optional barrier layer 308 may include the same material as the optional barrier layer 222. After the formation of the conductive feature 306, a planarization process may be performed. As a result, a portion of the mask 302 remains, and the mask 302 includes a surface substantially coplanar with a surface of the conductive feature 306, as shown in FIG. 20D. Subsequent processes include depositing an etch stop layer 310 (FIGS. 21A, 21B) on the mask 302 and the conductive feature 306, depositing a dielectric material 312 (FIGS. 21A, 21B) on the etch stop layer 310, and depositing conductive features 314a, 314b (FIGS. 21A, 21B) in the dielectric material 312. The etch stop layer 310 may include the same material as the CESL 162. The dielectric material 312 may be an IMD layer. The conductive features 314a are formed to provide electrical paths to the S/D regions 146 and the gate electrode layers 172 from the back side of the semiconductor device structure 100. The conductive feature 314b are formed to be electrically connected to the conductive feature 306. The conductive features 314a, 314b may include the same material as the conductive features 228a, 228b. In some embodiments, an optional barrier layer 316 is formed to separate the conductive features 314a, 314b from the dielectric material 312. The optional barrier layer 316 may include the same material as the optional barrier layer 222. In some embodiments, the dielectric material 312 including the conductive features 314a, 314b disposed therein may be the bottommost layer (or topmost layer when the front side of the semiconductor device structure 100 is on top) of a backside interconnect structure. Subsequent processes may include forming multiple layers of dielectric material with conductive features formed therein.

FIGS. 21A-21B are cross sectional side views of one of various stages of manufacturing the semiconductor device structure 100 taken along lines A-A, B-B of FIG. 16A, respectively, in accordance with some embodiments. After forming the backside interconnect structure, the semiconductor device structure 100 is flipped back so the front side of the semiconductor device structure 100 is located on top. As shown in FIGS. 21A and 21B, in some embodiments, the FTV cell includes the conductive feature 220b, the conductive features 212b, and the conductive feature 306, and the FTV cell is electrically connected to the front side interconnect structure and the backside interconnect structure. The FTV cell is formed in an isolation region between active devices, such as between logic cells. In some embodiments, as shown in FIG. 21A, a width of the conductive feature 306 along the X direction is greater than the first width of the top portion 220bt of the conductive feature 220b. In some embodiments, the width of the conductive feature 306 is greater than a combined width of the conductive features 212b and the conductive feature 220b, as shown in FIG. 21A. The width of the conductive feature 306 is less than the distance D1 (FIG. 18B), which may equal to two times CPP, in order to reduce the risk of electrical short between the conductive feature 306 and the adjacent active devices. Similarly, the length of the conductive feature 306 along the Y direction is less than the second length of the dielectric material 208 and less than the cell height of the FTV cell, as shown in FIG. 21B. In some embodiments, the length of the conductive feature 306 is less than the length of the conductive feature 220b, as shown in FIG. 21B, because the conductive feature 306 is located between adjacent substrate portions 116, while the conductive feature 220b is not limited by the substrate portions 116.

FIGS. 22A and 22B are perspective views of a feed through via (FTV) cell, in accordance with some embodiments. The dielectric materials, such as the dielectric material 208, the ILD layer 163, the CESL 162, the spacer 140, the etch stop layer 216, the dielectric material 218, the liner 205, and the dielectric material 206, of the FTV cell are omitted for clarity. As shown in FIGS. 22A and 22B, the FTV cell includes the conductive feature 220b disposed on and between the conductive features 212b. The top portion 220bt is disposed on the conductive features 212b, and the bottom portion 220bb is disposed between the conductive features 212b. In some embodiments, each conductive feature 212b includes a top portion 212bt and a bottom portion 212bb. In some embodiments, the top portion 212bt has a width along the Y direction substantially greater than a width of the bottom portion 212bb, as shown in FIGS. 22A and 22B. The top portion 212bt of the conductive feature 212b may be disposed over two S/D regions 146, while the bottom portion 212bb of the conductive feature 212b is disposed between the two S/D regions 146, as shown in FIG. 22B. The two S/D regions 146 are formed over two substrate portions 116, and the conductive feature 306 is disposed between the two substrate portions 116, as shown in FIG. 22B. In some embodiments, the conductive feature 306 include side portions 306a disposed adjacent the side surface of the conductive feature 212b, as a result of the etch process that forms the opening to expose the conductive features 212b and the conductive feature 220b. The etch process may be a selective etch process that removes the dielectric material but not the metal(s) of the conductive features 212b, 220b. Portions of the liner 210 and ILD layer 163 located adjacent the side surfaces of the conductive feature 212b may be removed by the etch process.

FIG. 23 is a top view of the semiconductor device structure 100, in accordance with some embodiments. Some components of the semiconductor device structure 100 are omitted in FIG. 23 for clarity. As shown in FIG. 23, the dielectric materials 206 are formed to cut off the gate electrode layers 172, and the dielectric materials 208 are formed in some of the gate electrode layers 172 located between the two dielectric materials 206. The FTV cell is formed between the two dielectric materials 206 and between the two outer most dielectric materials 208 along the X direction. The FTV cell includes the conductive feature 220b disposed on and between the conductive features 212b, and the conductive feature 306 is electrically connected to the conductive features 220b, 212b. The conductive features 220b, 212b, 306 can reduce electrical resistance in the FTV cell. As described above, in some embodiments, the FTV cell is within two times CPP, and the electrical resistance of the FTV cell is about 40Ω, which is substantially less than that of a conventional FTV cell.

FIG. 24 is a perspective view of the semiconductor device structure 100, in accordance with some embodiments. As shown in FIG. 24, a signal transmits from a driver cell to a receiver cell using two FTV cells. The signal is transmitted from the driver cell to a backside interconnect structure 402 of the semiconductor 100 via a first FTV cell, and the signal is transmitted from the backside interconnect structure 402 to the receiver cell via a second FTV cell, as shown in FIG. 24. The conductive features in the backside interconnect structure 402 have lower resistance because it is less crowded in the backside interconnect structure 402. As described above, the electrical resistance in the FTV cells is also reduced. As a result, cell speed is improved.

FIGS. 25A-25B are cross-sectional side views of one of various stages of manufacturing the semiconductor device structure 100 taken along lines A-A, B-B of FIG. 16A, respectively, in accordance with alternative embodiments. In some embodiments, the conductive feature 306 is not formed, instead, the conductive feature 220b extends into the isolation region 120. In such embodiments, the substrate removal or thin down process shown in FIG. 20B exposes the conductive feature 220b. Thus, in some embodiments, the FTV cell includes the conductive feature 220b having the top portion 220bt and the bottom portion 220bb. The bottom portion 220bb may have a height along the Z direction substantially greater than the height of the conductive feature 212b. In some embodiments, the bottom portion 220bb is disposed between the substrate portions 116, as shown in FIG. 25B.

FIG. 26 is a cross-sectional side view of one of various stages of manufacturing the semiconductor device structure 100 taken along line A-A of FIG. 16A, in accordance with alternative embodiments. Some components of the semiconductor device structure 100 are omitted in FIG. 26 for clarity. As shown in FIG. 26, in some embodiments, the FTV cell is defined by two dielectric materials 208 that are four times CPP apart along the X direction. Four conductive features 212b are formed in the ILD layer 163, and the conductive feature 220b includes the continuous top portion 220bt and discrete bottom portions 220bb. The bottom portions 220bb are disposed between adjacent conductive features 212b, as shown in FIG. 26. The conductive feature 306 is electrically connected to the conductive features 212b, 220b. In some embodiments, the FTV cell is located between two dielectric materials 208 that are six times CPP apart, and the electrical resistance of the FTV cell is around 10Ω, which is substantially less than that of a conventional FTV cell.

Embodiments of the present disclosure provide a semiconductor device structure 100 including a FTV cell having the conductive features 220b, 212b, 306. The conductive feature 220b may be disposed on and between the conductive features 212b, and the conductive feature 306 is electrically connected to the conductive features 220b, 212b. Some embodiments may achieve advantages. For example, the conductive features 220b, 212b, 306 arranged in various embodiments described herein can lead to reduced electrical resistance. Furthermore, the dimensions of the conductive feature 306 can lead to low area penalty of the FTV cell.

An embodiment is a semiconductor device structure. The structure includes a first conductive feature disposed between two substrate portions, a second conductive feature disposed over the first conductive feature, a third conductive feature disposed over the first conductive feature, and a fourth conductive feature disposed over the first conductive feature. The fourth conductive feature includes a top portion disposed over the second and third conductive features and a bottom portion disposed between the second and third conductive features, and the first, second, third, and fourth conductive features are electrically connected.

Another embodiment is a semiconductor device structure. The structure includes a first dielectric material extending across first and second gate electrode layers, a second dielectric material extending across the first and second gate electrode layers, a third dielectric material disposed in the first gate electrode layer between the first and second dielectric materials, a fourth dielectric material disposed in the second gate electrode layer between the first and second dielectric materials, and a feed through via (FTV) cell disposed between the first and second dielectric materials and between the third and fourth dielectric materials. The FTV cell includes a first conductive feature disposed between the third and fourth dielectric materials, and the first conductive feature has a first width and a first length. The FTV cell further includes a second conductive feature disposed over the first conductive feature and electrically connected to the first conductive feature. The second conductive feature has a second width and a second length, the second width is substantially greater than the first width, and the second length is substantially less than the first length.

A further embodiment is a method. The method includes depositing first and second conductive features in an interlayer dielectric layer, the first conductive feature is deposited over first and second source/drain regions, and the second conductive feature is deposited over third and fourth source/drain regions. The method further includes depositing a third conductive feature over and between the first and second conductive features, and the third conductive feature includes a top portion disposed on the first and second conductive features and a bottom portion disposed between the first and second conductive features. The method further includes depositing a fourth conductive feature, and the fourth conductive feature is electrically connected to the first, second, and third conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first conductive feature disposed between two substrate portions;
a second conductive feature disposed over the first conductive feature;
a third conductive feature disposed over the first conductive feature; and
a fourth conductive feature disposed over the first conductive feature, wherein the fourth conductive feature comprises a top portion disposed over the second and third conductive features and a bottom portion disposed between the second and third conductive features, and the first, second, third, and fourth conductive features are electrically connected.

2. The semiconductor device structure of claim 1, wherein the top portion of the fourth conductive feature has a first width, and the bottom portion of the fourth conductive feature has a second width substantially smaller than the first width.

3. The semiconductor device structure of claim 1, wherein the fourth conductive feature has a bottom located at a same level as bottoms of the second and third conductive features.

4. The semiconductor device structure of claim 1, wherein the fourth conductive feature has a bottom located at a level different from bottoms of the second and third conductive features.

5. The semiconductor device structure of claim 1, wherein the second and third conductive features each comprises a first metal, and the fourth conductive feature comprises a second metal different from the first metal.

6. The semiconductor device structure of claim 5, further comprising a first barrier layer in contact with the first conductive feature, the second conductive feature, and the third conductive feature.

7. The semiconductor device structure of claim 6, further comprising a second barrier layer in contact with the second, third, and fourth conductive features and the first barrier layer.

8. A semiconductor device structure, comprising:
a first dielectric material extending across first and second gate electrode layers;
a second dielectric material extending across the first and second gate electrode layers;
a third dielectric material disposed in the first gate electrode layer between the first and second dielectric materials;
a fourth dielectric material disposed in the second gate electrode layer between the first and second dielectric materials; and
a feed through via (FTV) cell disposed between the first and second dielectric materials and between the third and fourth dielectric materials, wherein the FTV cell comprises:
a first conductive feature disposed between the third and fourth dielectric materials, wherein the first conductive feature has a first width and a first length; and
a second conductive feature disposed over the first conductive feature and electrically connected to the first conductive feature, wherein the second conductive feature has a second width and a second length, the second width is substantially greater than the first width, and the second length is substantially less than the first length.

9. The semiconductor device structure of claim 8, further comprising a fifth dielectric material disposed between the first and second dielectric materials and between the third and fourth dielectric materials.

10. The semiconductor device structure of claim 9, wherein the first and second conductive features are disposed in the fifth dielectric material.

11. The semiconductor device structure of claim 8, further comprising a third conductive feature and a fourth conductive feature, wherein the third and fourth conductive features are disposed over the first conductive feature.

12. The semiconductor device structure of claim 11, wherein the second conductive feature comprises a top portion and a first bottom portion, and the first bottom portion is disposed between the third and fourth conductive features.

13. The semiconductor device structure of claim 12, further comprising a fifth conductive feature and a sixth conductive feature, wherein the fifth and sixth conductive features are disposed over the first conductive feature.

14. The semiconductor device structure of claim 13, wherein the second conductive feature further comprises a second bottom portion and a third bottom portion, the second bottom portion is disposed between the third and fifth conductive features, and the third bottom portion is disposed between the fourth and sixth conductive features.

15. A method for forming a semiconductor device structure, comprising:
depositing first and second conductive features in an interlayer dielectric layer, wherein the first conductive feature is deposited over first and second source/drain regions, and the second conductive feature is deposited over third and fourth source/drain regions;
depositing a third conductive feature over and between the first and second conductive features, wherein the third conductive feature comprises a top portion disposed on the first and second conductive features and a bottom portion disposed between the first and second conductive features; and
depositing a fourth conductive feature, wherein the fourth conductive feature is electrically connected to the first, second, and third conductive features.

16. The method of claim 15, further comprising depositing a first dielectric material over the interlayer dielectric layer, wherein the third conductive feature is deposited in the first dielectric material.

17. The method of claim 16, further comprising depositing a fifth conductive feature in the first dielectric material, wherein the third and fifth conductive features are deposited at different times using different masks.

18. The method of claim 15, further comprising flipping over the semiconductor device structure prior to depositing the fourth conductive feature.

19. The method of claim 15, wherein the third conductive feature surrounds three surfaces of the first conductive feature and three surfaces of the second conductive feature.

20. The method of claim 19, further comprising depositing a barrier layer, wherein the third conductive feature is deposited on the barrier layer.
